(19) United States
(12) Patent Application Publication
(10) Pub. No.: US 2009/0294871 A1
(43) Pub. Date: Dec. 3, 2009

(54) SEMICONDUCTOR DEVICES HAVING RARE EARTH METAL SILICIDE CONTACT LAYERS AND METHODS FOR FABRICATING THE SAME

(75) Inventor: Paul R. BESSER, Sunnyvale, CA (US)

Correspondence Address: INGRASSIA FISHER & LORENZ, P.C. (AMD), 7010 E. COCHISE ROAD, SCOTTSDALE, AZ, 85253, US

(73) Assignee: ADVANCED MICRO DEVICES, INC., Austin, TX (US)

(21) Appl. No.: 12/130,263

(22) Filed: May 30, 2008

(51) Int. Cl. H01L 29/78; H01L 21/44; H01L 21/336

(52) U.S. Cl. 257/384; 438/682; 438/301; 257/E21.476; 257/E21.409; 257/E29.255

(57) ABSTRACT

MOS transistors and methods for fabricating MOS transistors are provided. One exemplary method comprises providing a substrate having a silicon-comprising surface region. A first metal silicide layer is formed overlying the silicon-comprising surface region. Ion implantation is used to implant rare earth metal ions at an interface between the first metal silicide layer and the silicon-comprising surface region. The substrate is heated to form a second rare earth metal silicide layer disposed below the first metal silicide layer.

### FIELD OF THE INVENTION

The present invention generally relates to semiconductor devices and methods for fabricating semiconductor devices, and more particularly relates to semiconductor devices having rare earth metal silicide contact layers and methods for fabricating such semiconductor devices.

### BACKGROUND OF THE INVENTION

Cobalt silicide (CoSi₂) has been used widely for contact layers of 90 nm technology metal-oxide-semiconductor (MOS) devices. However, as device size continues to decrease to 65 nm technologies and beyond, the use of CoSi₂ becomes more difficult. In particular, voiding in the CoSi₂ contact causes narrow linewidth effects (NLE) to occur where reductions in the gate length below a threshold of about 40 nm lead to drastic increases in contact resistance. In addition, CoSi₂ is relatively incompatible with embedded silicon germanium integration schemes and tends to consume significant amounts of silicon associated with silicon-on-insulator (SOI) substrates. Nickel silicide (NiSi) has become a viable alternative to CoSi₂. NiSi eliminates the contact resistance challenges associated with scaling, is compatible with SiGe substrates, and consumes less silicon. However, NiSi is not without its challenges: 1) the nickel-disilicide (NiSi₂) phase has been observed to form at very low temperatures; 2) excessive nickel diffusion has been observed on narrow active areas; and 3) NiSi can be morphologically unstable and can degrade through thermal grooving and agglomeration.

As gate dimensions and contact areas shrink beyond the 65 nm technology node, reducing the contact resistance (ρ_{c}) between silicide layers and underlying silicon becomes especially critical. NiSi and CoSi₂ each have mid-gap Schottky barrier heights of approximately 0.65 eV, and thereby offer sufficiently low ρ_{c} to provide acceptable performance in both PMOS and NMOS FET applications. However, computer models have demonstrated that further reductions in contact resistance can be achieved by tailoring the silicide layer to the type of FET used. Using this approach, the silicide layer material is chosen based on the magnitude of its Schottky barrier height, and its ability to reach the band edge for the particular FET type. Because the band for PMOS devices is different (lower) than that of NMOS devices, a different silicide material is selected for each type to provide improved optimization. This process is known as dual silicide integration, and requires using higher barrier height (relative to n-Si) materials in PFETs, and lower barrier height materials in NFETs. Silicides of platinum (Pt) and iridium (Ir) offer among the highest available barrier heights for silicide compounds, ranging from approximately 0.85 to 0.95 eV respectively, and accordingly may be good candidates for use in PMOS transistors. Conversely, silicides of certain rare earth (RE) metals have demonstrated Schottky barrier heights that are significantly lower than those of either CoSi₂ or NiSi, and consequently may provide a better match with NMOS devices. In particular, barrier heights for erbium (Er) and ytterbium (Yb) have been measured to be less than 0.30 eV, while those of dysprosium (Dy), gadolinium (Gd), and lutetium (Lu) have been measured at approximately 0.32 eV.

However, rare earth metal silicides used in bulk as NMOS silicide layers have microstructures that often contain defects and other harmful morphological characteristics. Further, because they form in a nucleation-controlled manner, they may begin to exhibit NLE on linewidths prohibitively large for advanced semiconductor device applications. Furthermore, many rare earth metals are known to be reactive with oxygen at elevated temperatures. This factor may also contribute to increased contact resistance if oxidation is allowed to occur during device fabrication. Processing techniques therefore must be developed to incorporate a rare earth metal silicide layer at the silicon/silicide interface over a source, drain, or gate to reduce overall contact resistance within NMOS devices, while avoiding the problems associated with oxidation and with using these materials as bulk layers.

Accordingly, it is desirable to provide semiconductor devices having rare earth metal silicide contact layers. Further, it is desirable to provide methods for fabricating semiconductor devices having rare earth metal silicide contact layers. Furthermore, other desirable features and characteristics of the present invention will become apparent from the subsequent detailed description of the invention and the appended claims, taken in conjunction with the accompanying drawings and this background of the invention.

### BRIEF SUMMARY OF THE INVENTION

A method for fabricating contacts for a semiconductor device in accordance with one exemplary embodiment of the invention is provided. The method comprises providing a substrate having a silicon-comprising surface region. A first metal silicide layer is formed overlying the silicon-comprising surface region. Ion implantation is used to implant rare earth metal ions at an interface between the first metal silicide layer and the silicon-comprising surface region. The substrate is heated to form a second rare earth metal silicide layer disposed below the first metal silicide layer.

A method for fabricating an NMOS transistor on a silicon substrate having a surface in accordance with a further exemplary embodiment of the invention is provided. The method comprises forming a gate stack disposed on the surface of the silicon substrate. N-doped silicon regions are formed at the surface of the silicon substrate adjacent to the gate stack. A first metal silicide layer is formed overlying the n-doped silicon regions. Ions of a rare earth metal are implanted through the first metal silicide layer to a region within the n-doped silicon regions. The substrate is annealed to form a rare earth metal silicide layer disposed underlying the first metal silicide layer, wherein the compositions of the first metal silicide layer and the rare earth metal silicide layer are different.

An MOS transistor in accordance with yet another exemplary embodiment of the invention is provided. The MOS transistor comprises a silicon substrate having a surface. An impurity-doped region is disposed at the surface of the silicon substrate. A first metal silicide layer is disposed at the surface of the impurity-doped region. A rare earth metal silicide layer different than the first metal silicide layer is disposed underlying the first metal silicide layer.

### BRIEF DESCRIPTION OF THE DRAWINGS

The present invention will hereinafter be described in conjunction with the following drawing figures, wherein like numerals denote like elements, and wherein:

FIGS. 1-5 illustrate methods for fabricating an MOS transistor in accordance with exemplary embodiments of the present invention.

### DETAILED DESCRIPTION OF THE INVENTION

The following detailed description of the invention is merely exemplary in nature and is not intended to limit the invention or the application and uses of the invention. Furthermore, there is no intention to be bound by any theory presented in the preceding background of the invention or the following detailed description of the invention.

The various embodiments of the present invention result in the fabrication of an NMOS transistor having a contact layer composed of two different silicide layers, one underlying the other. This bilayer laminar structure overlies the gate and/or source and drain of an NMOS transistor and provides a conducting surface through which other devices in the circuit may interconnect. The top silicide layer may be based on either Ni or Co and is formed in gate, source, and drain regions using a series of deposition, etch, and anneal processes which will be described in greater detail subsequently. In accord with an embodiment of this invention, a second silicide layer is formed subsequent to and underlying the first layer. The second layer is formed using a controlled high energy ion implantation process to embed selected rare earth elements such as Er, Yb, Dy, Gd and Lu at or near the silicon/silicide interface by implanting them through the first silicide layer. Thus, the second rare earth metal silicide (RESiₓ) layer is formed at the silicon/first silicide interface and is shielded from oxidative effects by the overlying first silicide layer.

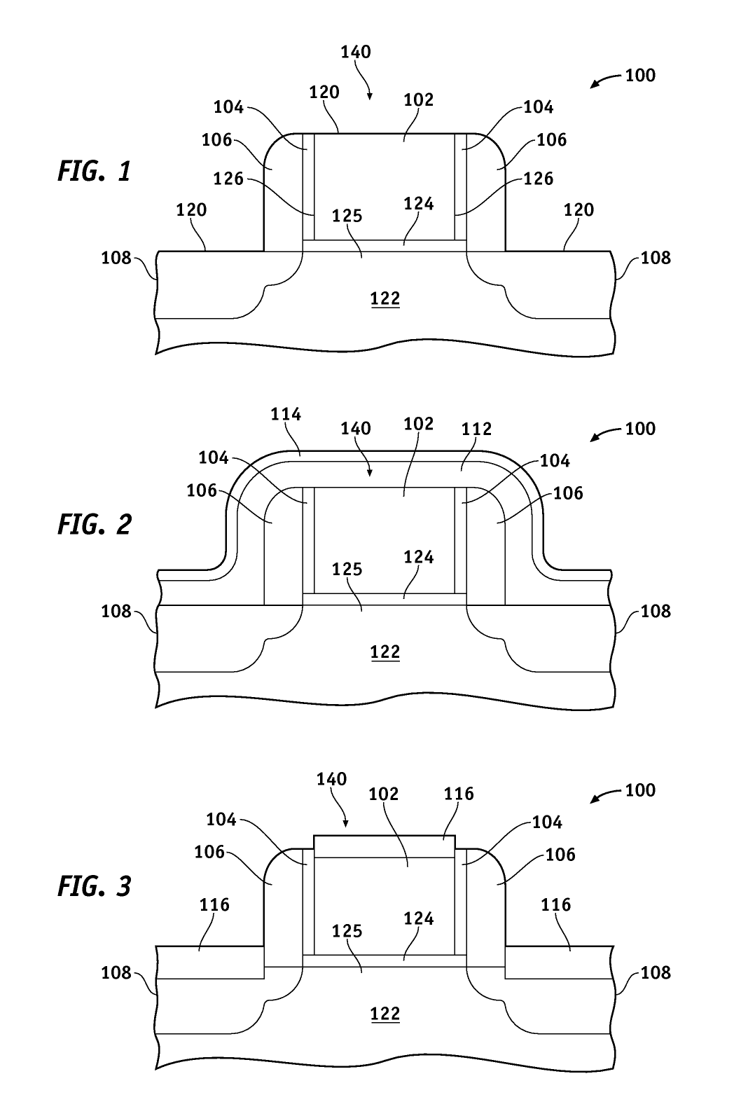

FIGS. 1-5 illustrate schematically in cross section, methods for forming an MOS transistor 100 in accordance with exemplary embodiments of the invention. Although the term “MOS transistor” properly refers to a device having a metal gate electrode and an oxide gate insulator, that term will be used throughout to refer to any semiconductor device that includes a conductive gate electrode (whether metal or other conductive material) that is positioned over a gate insulator (whether oxide or other insulator) which, in turn, is positioned over a silicon-comprising substrate. The embodiments herein described refer to an N-channel MOS (NMOS) transistor. While the fabrication of only one NMOS transistor is illustrated, it will be appreciated that the method depicted in FIGS. 1-5 can be used to fabricate any number of such transistors. Various steps in the manufacture of MOS components are well known and so, in the interest of brevity, many conventional steps will only be mentioned briefly herein or will be omitted entirely without providing the well known process details.

Referring to FIG. 1, the method begins by providing a substrate 122 that is a monocrystalline silicon substrate having a P-type doping. The term “silicon substrate” is used herein to encompass the relatively pure silicon materials typically used in the semiconductor industry as well as silicon admixed with other elements such as germanium, carbon, and the like. The silicon substrate may be a bulk silicon wafer, or may be a thin layer of silicon on an insulating layer (commonly know as silicon-on-insulator or SOI) that, in turn, is supported by a carrier wafer. In this embodiment, a silicon substrate 122 having a P-type doping is used to fabricate an N-channel (NMOS) device.

In accordance with one embodiment, using a series of deposition, lithography, and etch steps that are well known to those skilled in the art, other components of MOS transistor 100 are fabricated. These include a gate electrode 102 that in at least one embodiment is comprised of polycrystalline silicon (or polysilicon). Insulating reoxidation sidewall spacers 104 having a thickness of 3-4 nm are formed about the sidewalls 126 of gate electrode 102. Offset sidewall spacers 106 are formed over the surfaces of the reoxidation sidewall spacers 104 by the anisotropic etching of a thicker blanket-deposited layer of silicon dioxide. While FIG. 1 illustrates NMOS transistor 100 with reoxidation sidewall spacers 104 and offset sidewall spacers 106, it will be understood that any type and number of spacers as is suitable for a desired application can be used. A gate insulator layer 124 comprised of silicon dioxide is disposed between the gate electrode 102 and a channel region 125 of substrate 122, and provides electrical insulation therebetween. The source and drain regions 108 are formed by the appropriate impurity doping of silicon substrate 122 in a known manner, for example, by ion implantation of dopant ions, and subsequent thermal annealing. A gate stack 140 comprising reoxidation spacers 104, offset spacers 106, gate electrode 102, and gate insulator layer 124 acts as an ion implantation mask and enables the self-alignment of source and drain regions 108 with the gate stack 140. For an N-channel NMOS transistor, the source and drain regions 108 are preferably formed by implanting arsenic ions, although phosphorus or antimony ions may also be used. In an embodiment, the source and drain regions 108 may also include either germanium or carbon to create compressive or tensile stress respectively in the channel region 125 of the transistor. MOS transistor 100 may be cleaned to remove any oxide that has formed on silicon comprising surfaces 120 using, for example, a wet etchant such as buffered hydrofluoric acid (BHF), or dilute hydrofluoric acid.

Referring to FIG. 2, a silicide-forming metal film 112 is deposited over MOS transistor 100. In a further embodiment, the metal film 112 comprises cobalt. Next, a capping layer 114 is formed overlying the metal film 112. The capping layer 114 acts as a barrier layer preventing the oxidation of the metal film 112 during subsequent annealing processes. Metal film 112 and capping layer 114 may be deposited using a physical vapor deposition (PVD) process such as sputtering or evaporation, or any other suitable metal deposition process. In one exemplary embodiment, the capping layer 114 is comprised of titanium (Ti) or titanium nitride (TiN) having a thickness of about 2-10 nm. MOS transistor 100 is next subjected to a first annealing process such as by, for example, rapid thermal annealing (RTA). In one exemplary embodiment, MOS transistor 100 is annealed for a range of about 5 to 50 seconds at a temperature of about 450 to 550° C., preferably for about 30 seconds at about 500° C. The anneal causes the silicide-forming metal to react with silicon, with which it is in contact, to form a monosilicide (CoSi) species. The silicide-forming metal overlying non-silicon surfaces, such as spacers 104 and 106, remains unreacted and can be removed along with the entire capping layer 114 using a wet etch process. Wet echants that may be used include solutions of sulfuric acid mixed with either hydrogen peroxide or ammonium peroxide. Following this etch, the MOS transistor 100 is subjected to a second annealing process. The step of annealing may be performed using RTA, laser annealing, or another appropriate annealing process. For example, the MOS transistor 100 can be subjected to RTA for a time ranging from about 5 to about 30 seconds at a temperature range of about from 650 to 800° C., preferably for 10 seconds at 700° C., to convert the monosilicide layer (CoSi) to a disilicide (CoSi₂) layer.

In another embodiment, the silicide-forming metal film 112 comprises nickel. The nickel film may include about 5-20 atomic % of Pt which can be easily accommodated in a PVD system by using a target of the desired composition. The capping layer 114 of FIG. 2 used to protect the cobalt from oxidation is not required when Ni or Ni/Pt metal films are applied because these films are much less reactive with oxygen than cobalt during subsequent annealing steps. After deposition, the nickel film 112 is subjected to a first annealing process such as by, for example, RTA. In one exemplary embodiment, the nickel film 112 is subjected to RTA for a time range of about from 5 to 30 seconds at a temperature range of about from 300 to 450° C. During the first anneal, as described above for the case of cobalt, nickel in contact with silicon such as in the gate electrode 102 and source and drain regions 108 reacts with the silicon to form a first phase of either nickel-rich silicide (NiₓSi) or nickel silicide (NiSi), depending on the RTA time and temperature, the substrate surface conditions, and the substrate dopant level and type. Unreacted nickel, such as nickel not in contact with silicon, may be removed selectively by, for example, a wet etching solution comprised of fuming nitric acid (HNO₃) and hydrochloric acid (HCl) mixed typically in a 1:3 volumetric ratio (commonly referred to as Aqua Regia). In accordance with one embodiment, the first phase nickel (or nickel-rich) silicide is subjected to a second annealing process. For example, the nickel silicide may be subjected to RTA at temperatures ranging from about 400 to about 500° C. to complete the transformation to the low-resistance phase of NiSi. In a further embodiment, the second annealing step may be optionally omitted provided subsequent thermal processing of MOS transistor 100 is adequate to achieve the same NiSi phase change. Care needs to be taken to keep the thermal budget low enough to avoid formation of the thermodynamically stable but highly resistive nickel disilicide phase (NiSi₂). FIG. 3 illustrates MOS transistor 100 following the formation of the second phase metal silicide layer 116 (CoSi₂ or NiSi) and the removal of all unreacted metal and, if used, the capping layer 114.

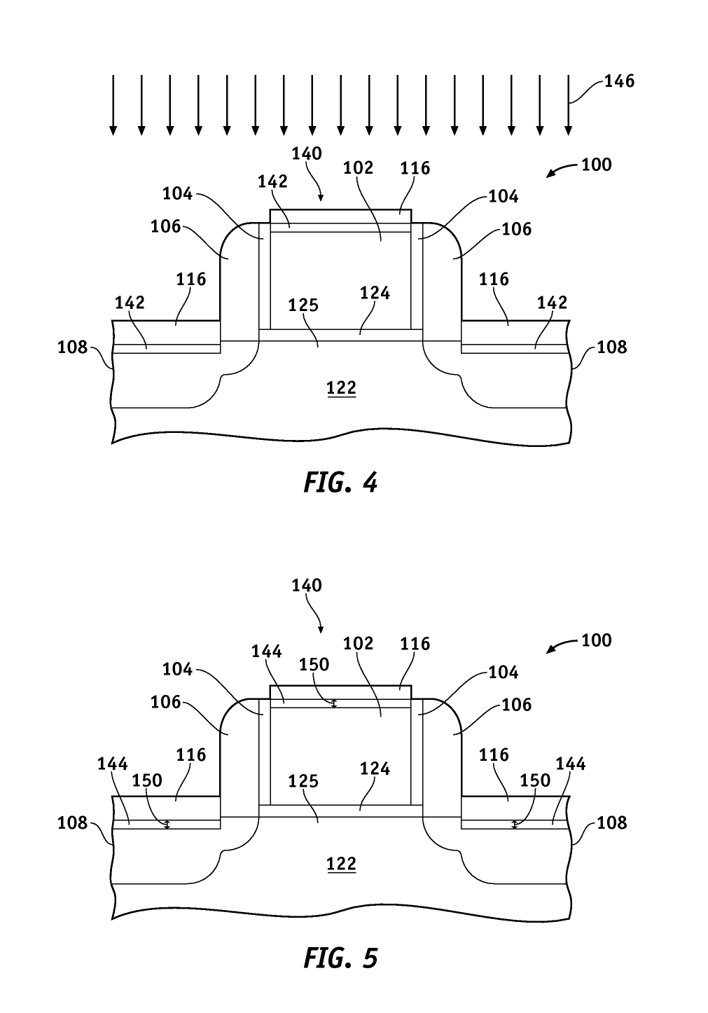

Referring to FIG. 4, after formation of metal silicide layer 116 and removal of the unreacted silicide-forming metal, a second silicide layer is formed underlying the first silicide layer 116. In one exemplary embodiment, ion implantation (as represented by the arrows 146) is used to implant ions of a selected RE metal through the first metal silicide layer 116 to form a thin RE metal ion-implanted region 142. This integration would require lithographically patterning or masking the pMOS region to prevent implantation here, as it is desirable to implant the RE metal ions into the nMOS transistor devices. The RE metal ion-implanted region 142 is disposed within the gate electrode 102 and source and drain 108 regions beneath and adjacent to first metal silicide layer 116. The RE metal species may comprise erbium (Er), ytterbium (Yb), gadolinium (Gd), dysprosium (Dy), lutetium (Lu), or any combinations thereof.

The accelerating voltage used to implant RE metal ions can be adjusted to achieve the depth of penetration and concentration profile desired for the RE metal ions, and the result will generally depend upon many factors including but not limited to the species of ion implanted, the thickness of the metal silicide layer 116, and the desired average penetration depth. The dose current may also be varied to control the desired ion concentration. In one embodiment, an accelerating voltage range of about from 15 to 40 keV and a dose of about from 1.0×10¹³ to 8.0×10¹⁵ cm⁻² are used. In a preferred embodiment, an accelerating voltage of about 25 keV and a dose of about 5.0×10¹⁴ cm⁻² are used.

Referring to FIG. 5, the RE metal ion-implanted region 142 is transformed to a RE metal silicide layer 144 by performing an annealing process. In accordance with one embodiment, rapid thermal annealing is used to subject the silicon substrate 122 to a temperature ranging from about 450° C. to about 700° C. for a time of about 5 to about 50 seconds. In accordance with a preferred embodiment, the annealing step is performed at about 500° C. for about 10 seconds. In accordance with yet another embodiment, the step of annealing may be performed using laser annealing or other appropriate annealing process. During the annealing process, the RE metal ions within the ion-implanted region 142 (FIG. 4) react with silicon to form RE metal silicide layer 144. In a preferred embodiment, the RE metal silicide layer 144 has a thickness indicated by double-headed arrow 150, of about from 2 to 15 nm.

Accordingly, the contact regions of MOS transistor 100 comprise a bilayer laminar structure of two silicide layers of differing composition. Further, the rare earth metal silicide layer 144 is formed beneath and subsequent to the first metal silicide layer 116. This prevents surface oxidative reactions from occurring that would otherwise increase the contact resistance, ρ_{c}, of the RE metal silicide layer 144. Further, the first metal silicide layer 116 comprising either CoSi₂ or NiSi may be subsequently contacted using materials and process techniques conventional to MOS fabrication without modification. Therefore, the procedures described herein can be easily integrated into a more comprehensive process used to fabricate MOS devices.

While at least one exemplary embodiment has been presented in the foregoing detailed description of the invention, it should be appreciated that a vast number of variations exist. It should also be appreciated that the exemplary embodiment or exemplary embodiments are only examples, and are not intended to limit the scope, applicability, or configuration of the invention in any way. Rather, the foregoing detailed description will provide those skilled in the art with a convenient road map for implementing an exemplary embodiment of the invention, it being understood that various changes may be made in the function and arrangement of elements described in an exemplary embodiment without departing from the scope of the invention as set forth in the appended claims.

1. A method for fabricating contacts for a semiconductor device, the method comprising the steps of:
providing a substrate having a silicon-comprising surface region;
forming a first metal silicide layer overlying the silicon-comprising surface region;
implanting rare earth metal ions at an interface between the first metal silicide layer and the silicon-comprising surface region using an ion implantation process; and
heating the substrate to form a second rare earth metal silicide layer disposed below the first metal silicide layer.

2. The method of claim 1, wherein the step of implanting rare earth metal ions comprises the step of implanting ions selected from the group consisting of erbium (Er), ytterbium (Yb), gadolinium (Gd), dysprosium (Dy), lutetium (Lu), and a combination thereof.

3. The method of claim 1, wherein the step of implanting rare earth metal ions comprises the step of implanting the ions using an accelerating voltage range of about from 15 to 40 keV and a dose range of about from 1.0×10¹³ to 8.0×10¹⁵ cm⁻².

4. The method of claim 3, wherein the step of implanting rare earth metal ions comprises the step of implanting the ions using an accelerating voltage of about 25 keV and a dose of about 5.0×10¹⁴ cm⁻².

5. The method of claim 1, wherein the step of forming a first metal silicide layer comprises forming a cobalt disilicide layer (CoSi₂).

6. The method of claim 5, wherein the step of forming a first metal silicide layer comprises the step of forming a first metal silicide layer using an annealing process wherein the substrate is subjected to a temperature range of about from 450° C. to 550° C. for a time range of about from 5 to 50 seconds.

7. The method of claim 5, wherein the step of forming a first metal silicide layer comprises the step of forming a first metal silicide layer using an annealing process wherein the substrate is subjected to a temperature range of about from 650° C. to 800° C. for a time of about from 5 to 30 seconds.

8. The method of claim 1, wherein the step of forming a first metal silicide layer comprises forming a nickel silicide (NiSi) layer.

9. The method of claim 8, wherein the step of forming a first metal silicide layer comprises the step of forming a first metal silicide layer using an annealing process wherein the substrate is subjected to a temperature range of about from 300° C. to 450° C. for a time range of about from 5 to 30 seconds.

10. The method of claim 8, wherein the step of forming a nickel silicide (NiSi) layer comprises forming a nickel silicide layer wherein the atomic ratio of nickel to platinum ranges from about 4 to about 19.

11. The method of claim 1, wherein the step of heating comprises the step of heating by rapid thermal annealing.

12. The method of claim 1, wherein the step of heating comprises subjecting the substrate to a temperature of about 450° C. to about 700° C. for about 5 to about 50 seconds.

13. The method of claim 12, wherein the step of heating comprises the step of heating to a temperature of about 500° C. for about 10 seconds.

14. The method of claim 1, wherein the step of heating comprises the step of heating the substrate to form a second metal silicide layer having a thickness in the range of about from 2 nm to 15 nm.

15. A method of fabricating an NMOS transistor on a silicon substrate having a surface, the method comprising the steps of:
forming a gate stack disposed on the surface of the silicon substrate;
forming n-doped silicon regions at the surface of the silicon substrate adjacent to the gate stack;
forming a first metal silicide layer overlying the n-doped silicon regions;
implanting ions of a rare earth metal through the first metal silicide layer to a region within the n-doped silicon regions; and
annealing the substrate to form a rare earth metal silicide layer disposed underlying the first metal silicide layer, wherein the compositions of the first metal silicide layer and the rare earth metal silicide layer are different.

16. The method of claim 15, wherein the step of implanting ions of a rare earth metal comprises the step of implanting ions selected from the group consisting of erbium (Er), ytterbium (Yb), gadolinium (Gd), dysprosium (Dy), lutetium (Lu), and a combination thereof.

17. The method of claim 15, wherein the step of forming a first metal silicide layer comprises forming a first metal silicide layer selected from the group consisting of cobalt disilicide (CoSi₂) and nickel silicide (NiSi).

18. The method of claim 15, wherein the step of implanting ions of a rare earth metal comprises the step of implanting the ions using an accelerating voltage range of about from 15 to 40 keV and a dose range of about from 1.0×10¹³ to 8.0×10¹⁵ cm⁻².

19. The method of claim 15, wherein the step of annealing comprises using rapid thermal annealing.

20. (canceled)
